(19) United States
(12) Patent Application Publication
(10) Pub. No.: US 2012/0280209 A1
(43) Pub. Date: Nov. 8, 2012

(54) OPTOELECTRONIC DEVICES EMPLOYING PLASMON INDUCED CURRENTS

(75) Inventors: Dawn Bonnell, West Chester, PA (US); Parag Banerjee, Creve Coeur, MO (US); David Conklin, Wappingers Falls, NY (US); Sanjini Nanayakkara, Denver, CO (US)

(73) Assignee: The Trustees of the University of Pennsylvania, Philadelphia, PA (US)

(21) Appl. No.: 13/505,569

(22) PCT Filed: Oct. 25, 2010
(86) PCT No.: PCT/US2010/053932

§ 371 Date: Jul. 23, 2012

Related U.S. Application Data
(60) Provisional application No. 61/258,687, filed on Nov. 6, 2009.

(51) Int. Cl. H01L 51/46

(52) U.S. Cl. 257/21; 257/E51.015

(57) ABSTRACT

An electro-optical device includes a substrate on which first and second electrodes are formed. A plurality of nanoparticles are arrayed on the surface of the substrate between the first and second electrodes. The arrayed nanoparticles exhibit plasmonic activity in at least one wavelength band. A plurality of linking molecules are coupled between respective adjacent ones of the nanoparticles and between each of the electrodes and nanoparticles that are adjacent to the electrodes. The linking molecules are selected to exhibit photo-activity that is complementary to the arrayed nanoparticles.

### STATEMENT REGARDING FEDERALLY SPONSORED RESEARCH

The invention was made with U.S. Government support. The Government may have certain rights in the invention through the National Science Foundation under federal grant number DMR-0425780.

### FIELD OF THE INVENTION

The invention concerns photoelectric devices and, in particular, photoelectric devices that include photo-active molecules and exhibit plasmonic activity.

### BACKGROUND OF THE INVENTION

Metal nanostructures have been studied extensively in the field of nano-science. Nanostructures have interesting physical properties that make them ideal for fundamental research and applications. In particular, nanostructures made from noble metals (e.g., gold and silver) with their associated strong plasmon resonance have generated great interest. The fact that the plasmon response is a sensitive function of nanostructure geometry, coupled with synthetic advances that allow for controlled and systematic variations in nanostructure geometries, is leading to a dramatic increase in interest in this topic. This interest has caused the development of a new field called “plasmonics,” associated with the design and fabrication of nano-optical components that focus and manipulate light at spatial dimensions far below the classical diffraction limit. Applications of plasmonics include surface enhanced Raman spectroscopy (SERS) and chemical sensing. To date, the applications of plasmonics have been largely in the optical domain.

### SUMMARY OF THE INVENTION

In one aspect of the invention, an electro-optical device is provided which comprises a substrate on which first and second electrodes are formed. A plurality of nanoparticles are arrayed on the surface of the substrate between the first and second electrodes. The arrayed nanoparticles exhibit plasmonic activity in at least one wavelength band. A plurality of linking molecules are coupled between respective adjacent ones of the nanoparticles and between each of the electrodes and nanoparticles that are adjacent to the electrodes. The linking molecules are selected to exhibit photo-activity that is complementary to the arrayed nanoparticles.

### DESCRIPTION OF THE DRAWINGS

FIG. 1a is a perspective drawing that illustrates an electronic path through an array of linked nanoparticles; FIGS. 1b, 1c and 2 are schematic drawings that illustrates the linking of two nanoparticles as shown in FIG. 1

FIG. 3 is a perspective and side-plan view of an example photovoltaic device that may include linked arrays of nanoparticles as shown in FIG. 1a.

FIG. 4 is a side-plan view of an example photo-active switch that may include a linked array of nanoparticles as shown in FIG. 1a.

### DETAILED DESCRIPTION OF THE INVENTION

Metal nanoparticles respond to electromagnetic waves by creating surface plasmons or particle plasmons, collectively known as plasmons. These are localized collective oscillations of conductive electrons on the surface of the nanoparticles. When inter-particle distances are small, plasmons generated in neighboring nanoparticles can couple to one another creating locally intense electromagnetic fields. The coupled particles can then act as optical antennae capturing and refocusing light between them. Furthermore, the electrical properties of molecules linking such nanoparticles may be affected by these interactions. For example the molecules and metal nanoparticles may exhibit charge transfer in which an electron is transferred from the highest molecular orbital of the linking molecule to the Fermi level of the metal and from the Fermi level of the metal to the lowest unoccupied orbital of the molecule.

In addition, the inventors have determined that plasmons may be used to control the electrical properties of photo-active, electrically conductive organic molecules that are used to electrically couple the nanoparticles in an array of metal nanoparticles. In particular, the magnitude of the observed photoconductivity of interconnected plasmon-coupled nanoparticles can be tuned independently of the optical characteristics of the molecule.

According to the example embodiments of the invention described below, optically induced plasmons may be used to alter the electrical properties of molecular junctions, greatly enhancing electrical conduction across the junctions. One example device, described below, consists of a disordered array of gold nanoparticles fabricated on an insulating glass substrate. The nanoparticles are linked by conjugated multi-porphyrin chromophoric molecules.

Plasmonic activity in nanoparticle arrays depends on the size, shape distribution of and separation between the nanoparticles in the array. Whereas the sizes of the nanoparticles can be controlled by modification of the conditions under which they are synthesized, inter-particle distances may be determined by the nature of the organic molecules that link each nanoparticle to its neighbors.

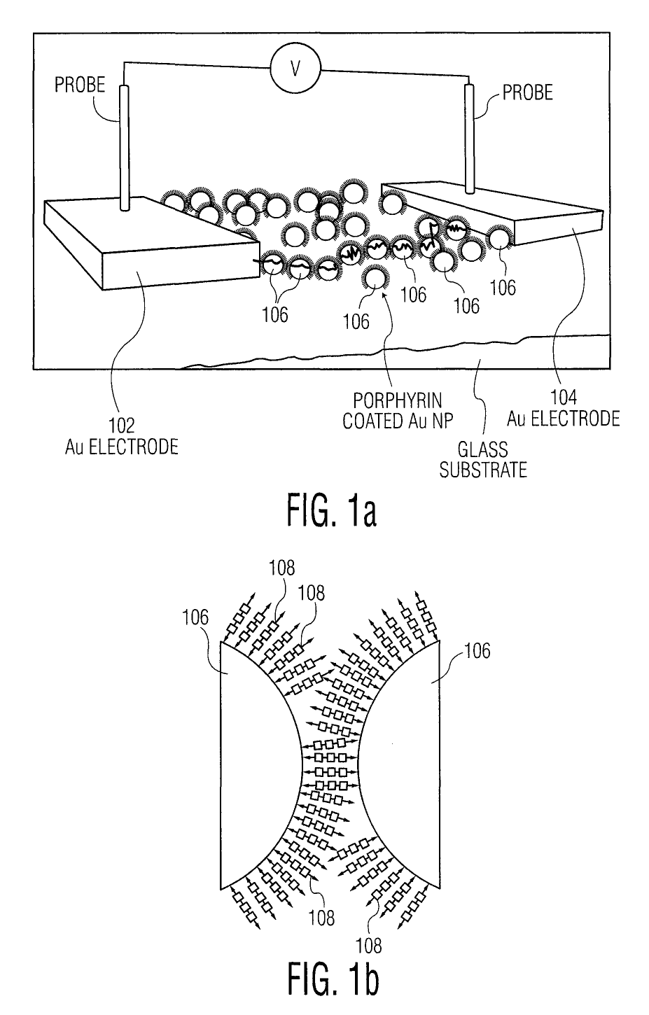

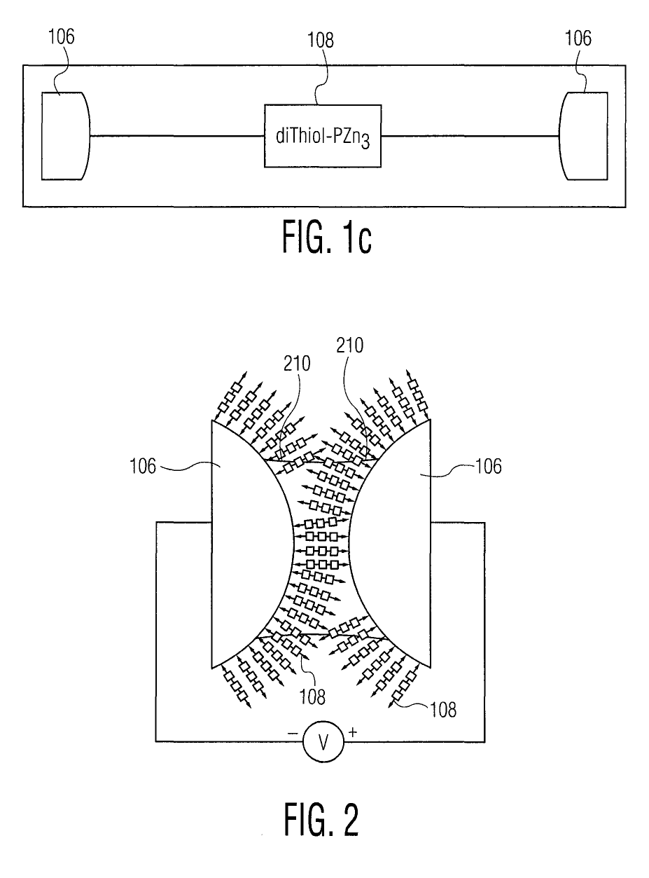

High-density closely packed arrays of nanoparticles exhibit metallic conductivities with resistances higher than that of the bulk material due to electron scattering at nanoparticle boundaries. At larger inter-particle separations, electrons can tunnel between nanoparticles. In such systems, temperature-dependent transport data may exhibit an Arrhenius dependence (σ αexp T ⁻¹) or suggest other conduction mechanisms, for example, (σ αexp T ^{-1/2}). In the case of a random array, however, conduction occurs via a percolative path spanning from one electrode to another. The percolative path comprises the “path of least resistance.” FIG. 1a shows an example of such a path between electrodes 102 and 104 formed by metal nanoparticles 106 that are coated with organic linking molecules.

The inventors have discovered a method for producing arrays of nanoparticles in which the separation between neighboring nanoparticles corresponds to, or is influenced by, the length of a conjugated molecule having appropriate linkage functionality at its termini. These molecules, linking the nanoparticles, ensure a percolative conduction path in the device.

An illustrative gold nanoparticle to gold nanoparticle interconnect is shown schematically in Fig. lb. As shown in FIG. 1b, nanoparticles 106 are joined by molecular interconnects 108. Nanoparticles 106 proximate to electrodes 102 and 104 may also be joined to the electrodes by molecular interconnects 108 (i.e., molecular interconnects 108 may bridge from a nanoparticle to an adjacent surface of an electrode).

In the example embodiments of the invention described below, the molecular interconnects (also referred to herein as linking compounds or linking molecules) are selected to have physical properties that are matched to the gold nanoparticles and possess optoelectronic characteristics optimal for coupling to plasmons generated in the array of gold nanoparticles and that exhibit charge transfer effects with the gold nanoparticles. For example, because isolated and coupled plasmon resonances in arrays of gold nanoparticles occur at wavelengths greater than or equal to 520 nm, it is desirable for the linking molecules to have a large absorptive oscillator strength in this regime of the electromagnetic spectrum. A meso-to-meso ethyne-bridged (porphinato)zinc(II) oligomer (PZnₙ compound, where n is 2 or greater) is one example of a molecule that exhibits this spectroscopic property. FIG. 1c shows the structure of an exemplary linking molecule 108 which serves as a 4.6 nm long gold nanoparticle to gold nanoparticle bridge in these devices.

When optical radiation excites plasmons and the nanoparticles are coupled, a large electromagnetic field may be established between the particles. As shown in FIG. 2, the particles 106 act as optical antennae and focus light into the region 210 between the particles. The size, shape, separation and distribution of the nanoparticles may be tailored to control both the wavelength of light at which the particles interact with the light and the regions into which they focus the light. Alternatively, the array of nanoparticles may exhibit a random distribution such that plasmonic activity exists in multiple wavelength bands. In addition, the optical excitation may contribute to the charge transfer between the particles and the molecular interconnects. The focused light has the consequence of increasing the photon flux at the molecular junction. When the size, shape and separation of the particles are controlled to produce “resonant” optical antennae, the conductivity of the array of nanoparticles may be enhanced by as much as 10^{4.}

In general terms, the size and shape of the nanoparticles as well as their spacing in the array may be controlled to sharpen or shift the plasmon and coupling energies as well as the antennae enhancement factor while the linking molecule may be designed to control the absorption wavelength, oscillator strength and the nature of excition and polaron states.

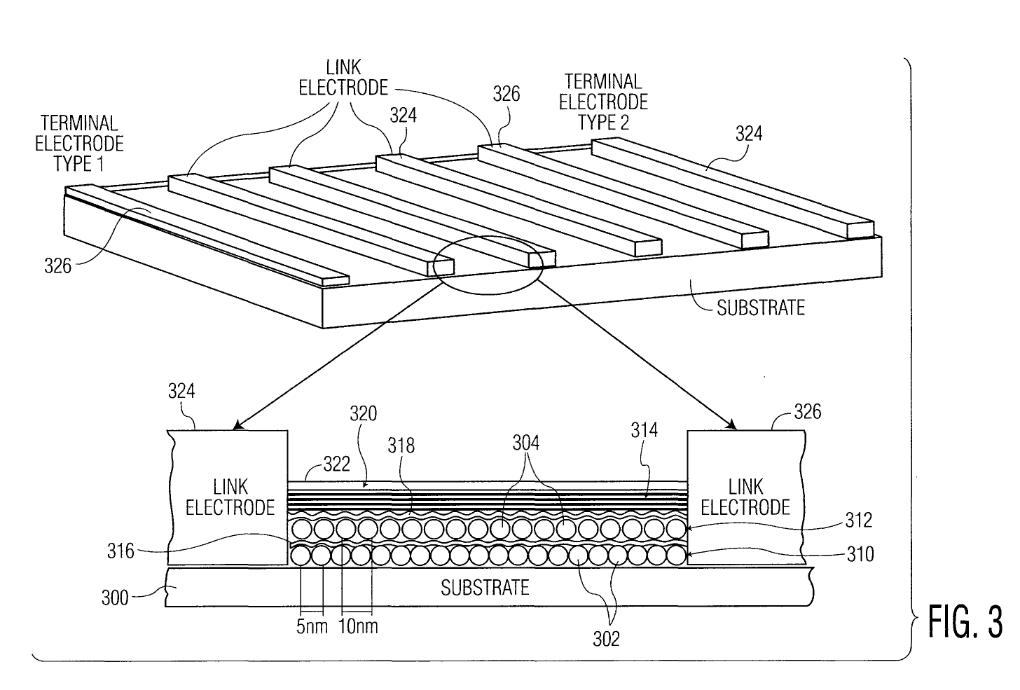

An illustrative photovoltaic device including an embodiment of the subject invention is shown in FIG. 3. In this example photovoltaic device, arrays of nanoparticles linked by photoactive linking molecules are arranged between electrodes having different Fermi levels. These electrodes form heterojunctions which attract the holes and electrons of the excitons generated in the linking electrodes in different directions. The enhanced conductivity of the array of nanoparticles due to the formation of plasmons as well as charge transfer effects makes it less likely that the holes and electrons of the excitons will recombine before reaching the electrodes.

The structure shown in FIG. 3 includes three layers, the bottom layer 310 is sensitive to red light, the middle layer 312 to green light and the top layer 314 to blue light. In the example embodiment, the bottom layer is formed from nanoparticles 302 on a glass substrate 300. In this example, the nanoparticles 302 may be coated with a linking molecule that exhibits absorptive oscillator strength in the red region of the spectrum. The coated nanoparticles may be randomly positioned on the substrate such that the average spacing between the nanoparticles without the linking molecules is approximately 5 nm. As described above, it is desirable for the coated nanoparticles to be in electrical contact. In this example embodiment, the nanoparticles may have diameters of in the range of 5-100 nm. In a particular array that is tuned to a specific wavelength band, the diameters of the particles are approximately equal. In this example the nanoparticles are generally spherical and have a diameter of approximately 30 nm. In the example, this layer of linked nanoparticles is the red sensitive layer 310.

A dielectric layer 316 of, for example, silicate glass is formed on top of the coated nanoparticles 302 of the bottom layer 310 and another layer of coated gold nanoparticles 304 is formed on top of the dielectric layer 316. The example nanoparticles 304 in this layer are coated with a linking molecule that exhibits absorptive oscillator strength in the green region of the spectrum. These nanoparticles, have approximately the same configuration as the nanoparticles in the red sensitive layer 310 except that they are randomly arranged on the dielectric layer 316 to have an average spacing of approximately 10 nm. This array of linked nanoparticles is the green sensitive layer 312. A second dielectric layer, which may also be silicate glass, is deposited on top of the linked nanoparticles of the green sensitive layer 312. On top of this layer is deposited a layer 320 of photo-active molecules that exhibit a relatively large absorptive oscillator strength in the blue region of the spectrum. This layer is the blue sensitive layer 314. A spun-on glass layer 322 is formed on top of the layer 320 to seal the device. In this example, the nanoparticles may be formed from gold and the is linking molecule may be dithiol PZn₃ (containing three zinc porphyrin moieties linked by ethynyl groups and functionalized at each end of the molecule with a thiol group).

Each of the layers 310, 312 and 314 is formed to be in electrical contact with two electrodes, anode 324 and cathode 326. As described above, these electrodes have different Fermi levels and, so, form a heterojunction with the intervening nanoparticle arrays. In this example, electrode 324 may be formed from an N-type semiconductor, for example, N-type silicon while electrode 326 may be formed from a metal, for example, gold. The example photovoltaic device includes alternating electrodes 324 and 326 where each pair of electrodes is separated by layers 310, 312 and 314 as described above. All of the anode electrodes 324 are electrically connected on one side of the device while all of the cathode electrodes 326 are electrically connected on the other side of the device.

In operation, white light impinging on the device generates excitons in all three layers. In the red layer 310, red components of the white light also generate plasmons that increase the conductivity of the linking molecules in the red layer, allowing the holes to migrate to the anode electrode 324 and the electrons to migrate to the cathode electrode 326. Similarly, green components of the white light generate plasmons in the green layer 312 increasing the conductivity of that layer so that holes and electrons of the excitons generated in layer 312 migrate to the electrodes 326 and 324, respectively. The top layer does not include nanoparticles because, as described above, blue light (i.e. light having wavelengths less than 520 nm) does not interact with gold nanoparticles to generate plasmons. The layers are arranged with the blue layer 314 on the top, the green layer 312 in the middle and the red layer 310 on the bottom because relatively little blue light will propagate through the layer 314 and relatively little green light will propagate through layer 312.

In this example embodiment, dithiol-PZn₃ has a relatively large absorption oscillator strength in the blue wavelength band and reduced absorption oscillator strength in the green and red wavelength bands. The augmented conductivity generated by the arrays of nanoparticles in the red and green layers allows the photocharges generated in these layers to contribute at about the same level as the blue photocharges generated in the top layer 314. It is contemplated that the device may be improved by using respectively different linking molecules having high absorption oscillator strength in the green and red wavelength bands, 312 and 310 in place of the dithiol-PZn₃. These molecules are selected to form bonds with the gold nanoparticles as well as with the electrodes 324 and 326. In addition, it is contemplated that other materials than gold may be used for the nanoparticle array and that the size and spacing of the nanoparticles may be changed as long as the result is red and green arrays that exhibit plasmonic activity in their respective wavelength bands.

Alternatively, a photovoltaic device which is sensitive to light in multiple wavelength bands may be made using randomly distributed linked nanoparticles which may have different sizes and shapes. Such an array may exhibit plasmonic activity in multiple wavelength bands. This example array may include a single linking molecule or multiple different linking molecules, each exhibiting increased sensitivity to light in a different wavelength band. Desirably, the photoactivity of the linking molecules is complementary to the plasmonic activity of the array of nanoparticles.

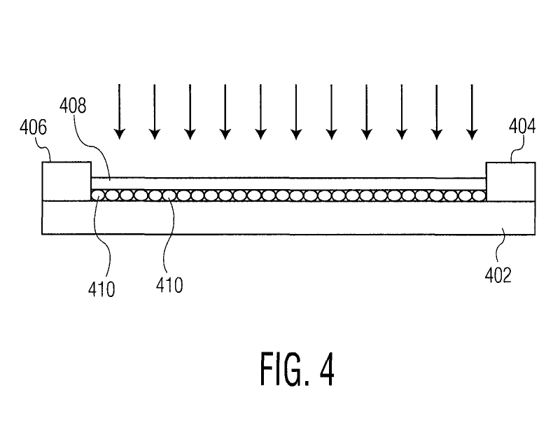

FIG. 4 is a side plan view of an example optical switch or light detector. This optical switch includes a single layer of linked metal nanoparticles 410, for example gold nanoparticles, formed on a glass substrate 402. The array of nanoparticles 410 is coupled to first and second electrodes 404 and 406 which may be, for example, gold electrodes. A protective spun-on glass layer 408 is formed over the array of nanoparticles 410.

In this example device, the linking molecule that joins the gold nanoparticles is selected to be conductive when illuminated by light in the desired wavelength band. In addition, the size and spacing of the gold nanoparticles are selected to generate plasmons and the linking molecules are selected to enhance charge transfer effects when illuminated in the desired wavelength band. Both the linking molecule and the configuration of the gold nanoparticles are selected to have much lower conductivity in wavelength bands outside of the desired band. In operation, the device shown in FIG. 4 may be coupled to positive and negative supplies and a current sensor may be placed in series with the device. When illuminated by light in the desired wavelength band, the conductivity of the device will increase, causing a greater current flow than when the device is illuminated by light in other wavelength bands.

The present invention utilizes nanoparticles. In one particularly advantageous aspect of the invention, at least a portion of the nanoparticles are particles comprised of metal which are electrically conductive. The nanoparticles should be capable of being induced to generate plasmons when subjected to optical interactions. That is, the nanoparticles should respond to electromagnetic waves by creating plasmons, which are localized, collective oscillations of conduction electrons. Preferably, the metal is selected from one or more of gold, silver, copper, a transition metal, or an element of groups 1B to IV of the periodic table. These include aluminum, scandium, titanium, vanadium, chromium, manganese, iron, cobalt, nickel, copper, is zinc, gallium, germanium, yttrium, zirconium, niobium, molybdenum, ruthenium, rhodium, palladium, silver, cadmium, indium, tin, lanthanum, hafnium, tantalum, tungsten, rhenium, osmium, iridium, platinum, gold, mercury, tellurium and lead. Gold may be an especially advantageous metal for use in the nanoparticles of the present invention. The metallic nanoparticles can be pure elemental metals or alloys or composites of different metals. A single type of metallic nanoparticle may be employed, but mixtures of different metallic particles varying in size, shape, elemental composition, and/or surface characteristics or the like are also usable.

The size of the nanoparticles may be varied as desired and may be selected so as to impart particular properties or characteristics to the arrays that are fabricated using such nanoparticles in accordance with the present invention. Generally speaking, however, the nanoparticles may range in size from about 1 nm to about 200 nm, with the range of from about 10 to about 100 nm being preferred in certain embodiments. As discussed previously, different layers or regions of a device in accordance with the invention may contain nanoparticles of different compositions and sizes. The nanoparticles may take the form of spheres, cubes, cones, discs, rods, tubes, wires, fibers or any other regular or irregular geometric shape.

In certain embodiments of the invention, ligand-stabilized metallic nanoparticles are employed as starting materials. Stabilizing metallic nanoparticles with ligands such as citrate can assist in keeping the nanoparticles from clustering together or agglomerating and in maintaining the nanoparticles as discrete, separated particles, while the nanoparticle arrays in accordance with the invention are being assembled. Deposition of nanoparticle arrays from such colloids results in a random distribution of positions (i.e., the nanoparticles are randomly distributed on a substrate surface). In an alternative embodiment of the invention, a stabilizing ligand is employed which is capable of linking the nanoparticles at a specified distance while in the colloid. This approach would result in nanoparticle arrays having more ordered and more closely packed position distributions, thereby increasing the number of nanoparticle pairs with the desired separation.

If so desired, the nanoparticles may be affixed to a substrate surface. For example, metallic nanoparticles may be chemically bonded to a substrate surface using one or more coupling agents, such as silane coupling agents. Suitable coupling agents include silanes which contain a functional group capable of being reacted with a metal in the metallic nanoparticle, such as an amino group, thiol group, or the like as well as a functional group capable of being reacted with a functional group on the surface of the substrate (for instance, where the substrate surface bears hydroxyl groups, the coupling agent may contain an alkoxy group or the like). In one embodiment of the invention, the coupling agent has little or no electrical conductivity (e.g., the coupling agent does not provide a conjugated structure connecting the substrate and the nanoparticles).

Compounds which are particularly preferred for use in linking nanoparticles in accordance with the present invention (sometimes referred to herein as “linking compounds” or “linking molecules”) include compounds which are conjugated, with the compound in one embodiment being comprised of at least one (but preferably more than one) chromophore per molecule selected from the group consisting of conjugated macrocycles and at least two end groups in each molecule that are capable of bonding to a metal. “Conjugated” in the context of the present invention means a chemical structure characterized by a chain wherein each contiguous atom in the chain possesses a p-orbital. For example, such a chain may contain a series of alternating carbon-carbon double (or triple) bonds and carbon-carbon single bonds. One or more aromatic rings may also comprise part of the conjugated structure.

The linking compounds may be “multichromophoric,” i.e., molecular entities containing more than one chromophore per molecule, in particular more than one conjugated macrocycle chromophore per molecule. If the compound contains more than one chromophore per molecule, the chromophores may be the same as or different from each other. “Chromophores” are chemical moieties capable of selective electromagnetic radiation absorption, particularly at visible light, ultraviolet, and near infrared wavelengths. For example, a chromophore can be a region or moiety in a molecule where the energy difference between two different molecular orbitals fall within the range of the visible spectrum. Visible light that hits the chromophore can thus be absorbed by exciting an electron from its ground state into an excited state. Typically, a chromophore takes the form of a conjugated pi system or a metal complex. The chromophores are preferably present in the main chain (“backbone”) of the linking compounds utilized in the present invention, but can also or alternatively be pendant to the main chain (e.g., in the form of substituents attached to the backbone of the linking compound). The chromophores may also be useful for creating the electron bands that are relevant for molecule to metal and metal to molecule charge transfers.

Conjugated macrocycles function as polarizable bridging moieties serving to augment electronic coupling between attached donor and acceptor groups. As such, any cyclic or polycyclic moieties comprising a plurality of unsaturations manifest as double or triple bonds can be used as a conjugated macrocycle in the present invention. In some embodiments, the conjugated macrocycles can be heterocyclic, comprising one or more heteroatoms. Some heterocyclic conjugated macrocycles include, but are not limited to, porphyrins, chlorins, phorbins, benzoporphyrins, bacteriochlorins, porphyrinogens, sapphyrins, texaphryins, and phthalocyanines, as well as N-confused versions of these species.

Conjugated macrocycles can also comprise one or more metal atoms such as, for example, transition metals, lanthanides, actinides, alkaline earth, and alkali metals. Further, any atom of the conjugated macrocycle can bear substituents, except possibly for atoms that are bonded to groups which interconnect conjugated macrocycles within the linking molecule. These substituents, as well as any metal atom complexed to the conjugated macrocycle, can be chosen for their particular steric or electronic properties, for instance, to control intramolecular interactions and/or molecular order in the bulk phase as well as to influence ground state and excited state energy levels. Conjugated macrocycle substituents can include H, electron-donating groups, and/or electron-withdrawing groups in any number and combination. More particularly, conjugated macrocycle substituents can include one or more of H, alkyl groups having 1 to about 20 carbon atoms, alkenyl groups having 2 to about 20 carbon atoms, alkynyl groups having 2 to about 20 carbon atoms, aryl groups having 3 to about 50 carbon atoms, arylalkynyl groups having 8 to about 24 carbon atoms, heterocycloalkyl groups having 2 to about 24 carbon atoms, heteroaryl groups having 2 to about 50 carbon atoms, heterocycloalkylalkynyl groups having 4 to about 24 carbon atoms, heteroarylalkynyl groups having 4 to about 50 carbon atoms, and groups including, but not limited to, halo, amino, nitro, nitroso, cyano, azido, aldehyde, carboxyl, carbonyl, alkylcarbonyl, alkoxycarbonyl, aminocarbonyl, alkoxy, hydroxyl, mercapto, thiolato, sulfo, phosphino, phospho, and phosphono, to name a few.

Conjugated macrocycles are well known in the art. For example, any of the conjugated macrocycle moieties described in U.S. Pat. No. 5,986,090 and U.S. Pat. Pub. Nos. 2004-0152826 and 2004-0067198 (each incorporated herein by reference in its entirety for all purposes) may be adapted for use in the present invention. Moieties other than conjugated macrocycles may also or alternatively be present as chromophores in the linking compounds used to construct nanoparticle arrays in accordance with the present invention. Such chromophoric moieties can include, for example, polypyridyl complexes of various metals such as ruthenium, osmium and iron as well as polycyclic aromatic systems such as fused or linked benzene ring systems, particularly polycyclic aromatic systems containing more than two benzene rings linearly attached to each other such as anthracene moieties and higher homologs thereof such as pentacene (including substituted polycyclic aromatic systems where the aromatic rings are substituted with one or more substituents other than hydrogen, such as halogen, alkyl, alkoxy, carboxylic acid, esters and/or cyano groups). The chromophores may be hydrocarbon in character (i.e., contain only carbon and hydrogen), but may also contain one or more heteroatoms such as oxygen, sulfur or nitrogen in addition to carbon and hydrogen. Functional groups such as ketones and the like may be present in the chromophore. The chromophore may also be a polycyclic aromatic moiety wherein one or more of the cyclic structures within such moiety contains one or more heteroatoms.

The compounds that may be used to link together metallic nanoparticles in accordance with the invention are characterized by having at least two end groups per molecule capable of bonding to a metal. In one embodiment, such compounds contain only two such end groups per molecule. The bonding may ionic or coordinative in nature, but in one advantageous embodiment the bonding is covalent. These end groups may either bond or react directly with a metal or after being treated or otherwise converted so as to remove a masking or protective group which initially is part of the end group. The end groups of the linking molecule may displace ligands present on the surface of the nanoparticles such as, for example, citrate ligands. In certain embodiments of the invention, the end groups are selected such that a metal to heteroatom bond is formed, particularly a metal to oxygen (e.g., M—O), metal to sulfur (e.g., M—S), or metal to nitrogen (e.g., M—N) bond, especially a covalent bond. In addition to N, O and S, other heteroatoms such as selenium, phosphorus, arsenic or tellurium can be similarly utilized. Suitable end groups include, for example, thiol (—SH) groups, amino groups (e.g., —NH₂, —NHR, or —NR₂, where R is an organic substituent such as an alkyl or aryl group), thiocarboxyl groups (e.g., a thioacetoxyl group —SCOCH₃), carboxyl (carboxylic acid) groups (—CO₂H), cyano groups (—CN), sulfonic acid groups, phosphonic acid groups or the like.

In one embodiment of the invention, the compound employed to link together the metallic nanoparticles to form arrays contains, in addition to one or more conjugated macrocyclic chromophores, one or more unsaturated carbon-carbon bonds such as carbon-carbon double bonds or carbon-carbon triple bonds. That is, the chain of the conjugated compound may contain one or more alkene and/or alkyne groups that are arranged so as to render the chain conjugated in character. Such alkene and alkyne groups may, for example, be interspersed between an end group and a conjugated macrocyclic chromophore and/or between two conjugated macrocyclic chromophores. Multiple alkene and/or alkyne groups may be arranged adjacent to each other. For example, two conjugated macrocyclic chromophores may be linked via conjugated connecting groups containing one or more carbon-carbon double and/or triple bonds. Thus, two adjacent macrocyclic chromophores may be connected to each other by an ethynyl group or a butadiynyl group. Aromatic groups (e.g., phenyl and/or fused benzene rings) may also be employed to construct the chain of the conjugated compound.

Each connecting group can be attached to any position on the conjugated macrocycle. For example, when the conjugated macrocycle is a porphyrin, the connecting group can be attached to meso or pyrrolic (beta) positions. In some embodiments, two connecting groups are attached at opposite meso positions in a porphyrin (i.e., at the 5 and 15 positions or the 10 and 20 positions on the porphyrin ring).

The compound that is used to treat or coat metallic nanoparticles in accordance with the invention may, for example, have the structure EG1-Cn1-[-MC-Cn2-]ₙ-EG2 wherein EG1 and EG2 are the same or different and are functional groups capable of bonding to a metal, Cn1 and Cn2 are the same or different and are conjugated connecting groups, MC is a chromophore selected from the group consisting of conjugated macrocycles, and n is an integer of at least 1, wherein if n is greater than 1 different chromophores may be present within the structure. In certain embodiments of the invention, EG1 and EG2 are AcS-Ph-, Cn1 and Cn2 are ethynyl groups, MC is a metalloporphyrin, and n is an integer of from 2 to 5. Meso-to-meso ethyne-bridged (porphinato)zinc(II) oligomers containing thiol end groups have been found to be particularly useful in the present invention. The value of n may be varied as desired to adjust the overall length of the linking molecule.

The aforementioned compounds thus can yield arrays of metallic nanoparticles comprising a structure M1-X-Cn1-[-MC-Cn2-]ₙ-Y-M2 wherein M1 and M2 are the same or different and are metal atoms on surfaces of metallic nanoparticles in the array, X and Y are the same or different and each contain a heteroatom selected from S and N bonded to M1 and M2 respectively, Cn1 and Cn2 are the same or different and are conjugated connecting groups, MC is a chromophore selected from the group consisting of conjugated macrocycles, and n is an integer of at least 1, wherein if n is greater than 1 different chromophores may be present within the structure. For example, X and Y may each be —S-Ph-, wherein sulfur is bonded to gold and the Ph (phenyl) group links to a connecting group Cn1 or Cn2.

Linking compounds useful in the present invention can be prepared by a variety of methods, including for example, metal-mediated cross-coupling techniques.

Metal-mediated cross-coupling is known to those skilled in the art as an efficient synthetic method for elaborating porphyrins and other related macrocycles as described in U.S. Pat. Nos. 5,371,199; 5,756,723; 5,986,090; and 5,493,017 as well as U.S. Pat. Pub. Nos. 2004-0152826 and 2004-0067198 and International Patent Application Publication WO 94/04614; and other publications including, DiMagno, et al., J. Am. Chem. Soc. 1993, 115, 2513; DiMagno, et al., J. Org. Chem. 1993, 58, 5983; and Lin, et al., Science, 1994, 264, 1105, each of which is incorporated herein by reference in its entirety for all purposes. Condensation techniques are also useful in the preparation of the present linking compounds and are described, for example, in DiMagno, et al., J. Org. Chem. 1994, 59, 6943.

In one aspect of the invention, useful linking compounds can be assembled by covalently coupling appropriately derivatized starting materials using metal-mediated cross-coupling techniques. One process for preparing linking compounds useful in the present invention involves contacting a conjugated macrocycle precursor, such as a porphyrin-containing or oligoporphyrin-containing precursor, with an end group precursor. The conjugated macrocycle precursor may comprise a conjugated macrocycle bearing at least one first reactive substituent such as an alkynyl group. In one embodiment, the conjugated macrocycle bears at least two such reactive substituents. If it is desired that the linking compound contain two or more conjugated macrocycles per molecule, oligomeric conjugated macrocycle precursors may be assembled using metal-mediated cross-coupling techniques.

The end group precursor comprises a moiety, typically an organic moiety, containing the desired end group (e.g., —SH) or precursor thereof (e.g., a masked or protected end group such as —SAc) and bearing a second reactive substituent such as a halogen (e.g., I, Br). The first and second reactive substituents are selected such that they are capable of participating in the desired metal-mediated cross-coupling reaction so as to form a covalent bond between the conjugated macrocycle precursor and the end group precursor. Contacting can be carried out in the presence of one or more metal-containing catalysts, such as a palladium-containing catalyst, under metal-mediated cross-coupling reaction conditions for a time and at a temperature sufficient to form the desired covalent linkage between the conjugated macrocycle precursor and end group precursor.

Appropriate catalysts and mechanisms for metal-mediated cross-coupling reactions are described in detail in U.S. Pat. No. 5,756,723, which is incorporated herein by reference in its entirety for all purposes. The principles and techniques relating to metal-mediated cross coupling are well known to those skilled in the art to consist of three general steps: (1) oxidative addition, (2) transmetalation, and (3) reductive elimination. See, e.g., Collman, et al., Principles and Applications of Organotransition Metal Chemistry, University Science Books, 1987, Mill Valley, Calif.; Kumada, Pure & Appl. Chem., 1980, 52, 669; Hayashi, et al., Tetrahedron Letters, 1979, 21, 1871, each of which is incorporated herein by reference in its entirety for all purposes.

The following publications also describe end-functionalized linking molecules containing chromophoric groups suitable for use in the present invention: WO 96/07487; US 2005/0056828; and US 2002/0127756, each of which is incorporated herein by reference in its entirety for all purposes. The molecular structure of the linking molecule may be varied as may be desired to modify the characteristics of the nanoparticle array. For example, the length of the linking molecule may be selected so as to influence or conform to the spacing of the nanoparticles in the array. Arrays may be produced in which the average separation between neighboring nanoparticles corresponds to the length of a linking molecule which is conjugated and which features appropriate linkage functionality at each terminus to ensure a percolative conduction path in a device containing an array of such interconnected nanoparticles. The chromophore(s) present in the linking molecule may be chosen to optimize coupling to metal plasmons.

Combinations or mixtures of different linking molecules which vary, for example, in chain length and/or chemical structure may be utilized in the present invention. Linking molecules of the same length which contain different chromophores or linking molecules of differing length containing the same type of chromophoric moieties (e.g., porphyrins) may be used within the same device. Different linking molecules may be employed in different layers or regions of the device. Although the invention is illustrated and described herein with reference to specific embodiments, the invention is not intended to be limited to the details shown. Rather, various modifications may be made in the details within the scope and range of equivalents of the claims and without departing from the invention.

### EXAMPLES

### Fabrication of Nanoparticle Arrays

To fabricate nanoparticle arrays, glass substrates (Fisher) were cleaned in piranha solution (1:3 30% H₂O₂: conc. H₂SO₄) for 10 minutes, rinsed with ultra-pure water, and immediately immersed into a 5% solution of 3-aminopropyl-methyl-diethoxysilane (Sigma-Aldrich) in hexanes (HPLC grade, Sigma-Aldrich). The glass substrates were kept in this solution at 80° C. for 24-48 hours. Citrate-stabilized AuNPs (gold nanoparticles) of diameters 16, 32, and 46 nm were synthesized according to a previously published methodology (Turkevich et al. Discussions of the Faraday Society, 55 (1951)). The amine-functionalized glass substrates were then immersed in aqueous solutions of AuNPs for ca. 96 hours under ambient conditions. The surface coverage and the particle size distribution of the AuNPs were established using dynamic light scattering (DLS) and scanning electron microscopy (SEM) in the as-prepared colloid, and on the substrate, respectively. Both techniques independently confirmed the size and size distribution of the AuNPs.

Adsorption of Dithiol-PZn₃ onto AuNP Arrays

Adsorption of dithiol-PZn₃ onto the AuNP (gold nanoparticle) arrays was performed under a nitrogen atmosphere in a glove box (PlasLabs). The solvent tetrahydrofuran (THF, HPLC grade, Fisher) was distilled from sodium under nitrogen and collected into a vacuum-sealed flask (Chemglass) and subjected to repeated freeze-pump-thaw-degas cycles. To an acetyl-protected dithiol-PZn₃ solution (ca. 1 μM in THF), 4 μl/ml of NH₄OH was added to unmask the thiolate functionality. The glass substrates with surface-bound AuNPs were then immersed into adsorption vials (Wheaton) containing this solution and set aside for 4 hours. The substrates were rinsed with THF and dried under a stream of N₂. Molecular attachment to the AuNPs was verified via electronic absorption spectroscopy, which showed the characteristic chromophore transition centered at 420 nm, and the AuNP plasmon band. Furthermore, the Raman spectra of these samples showed the strong surface-enhanced, characteristic peaks associated with the linker porphyrin system (Li et al. Thin Solid Films, 457, 372 (2004); Seth et al. J. Am. Chem. Soc., 116, 10578 (1994)). Gold electrodes (ca. 35 nm thick) separated by thin channels were thermally evaporated (Thermionics) on the AuNP covered glass substrate using a shadow mask technique. Channel lengths between the electrodes varying from 26 to 68 μm were obtained with this technique. The photoresponse of the devices prepared as described herein was found to be independent of this channel length. The samples were then transferred immediately to the probe station for electrical measurements.

The transport measurements were obtained using a Lakeshore Desert Cyrogenics TT6 probe station under vacuum and cooled using liquid nitrogen. Current-voltage (IV) characteristics were acquired with an electrometer (Keithley 6515A) using CuBe probe tips. After obtaining the transport data in the absence of illumination, the wavelength dependent current-voltage characteristics were obtained by exposing the samples to 405 nm (5 mW), 532 nm (2 mW), and 655 nm (5 mW) laser diodes (Edmund Optics). Transport properties were determined at temperatures ranging from 78 to 298° K.

What is claimed:

1. An electro-optical device comprising:
a substrate;
first and second electrodes formed on the substrate;
a plurality of nanoparticles on the surface of the substrate between the first and second electrodes wherein the plurality of nanoparticles exhibit plasmonic activity in at least one wavelength band; and
a plurality of linking molecules electrically coupled between respective adjacent ones of the plurality of nanoparticles, between the first electrode and ones of the plurality of nanoparticles adjacent to the first electrode and between the second electrode and ones of the plurality of nanoparticles adjacent to the second electrode, the plurality of linking molecules exhibiting photo-activity that is complementary to the plasmonic activity exhibited by the plurality of nanoparticles.

2. An electro-optical device according to claim 1, wherein the nanoparticles are metallic nanoparticles comprising at least one metal selected from the group consisting of copper, aluminum, silver, gold, lead and platinum.

3. An electro-optical device according to claim 1, wherein the linking molecules are conjugated molecules comprised of at least one chromophore and at least two end groups bonded to atoms on surfaces of the nanoparticles.

4. An electro-optical device according to claim 1, wherein the plurality of linking molecules exhibit photo-activity in a wavelength band that overlaps the at least one wavelength band in which the plurality of nanoparticles exhibit plasmonic activity.

5. An electro-optical device according to claim 4, wherein the wavelength band in which the plurality of nanoparticles exhibit plasmonic activity is narrower than the wavelength band in which the linking molecules exhibit photo-activity.

6. An electro-optical device according to claim 4, wherein the photo-activity exhibited by the linking molecules is absorption of photons and the plasmonic activity of the plurality of nanoparticles tends to enhance photon absorption in the linking molecules.

7. An electro-optical device according to claim 1, wherein the plurality of linking molecules exhibit less photo-activity in the wavelength band that overlaps the at least one wavelength band in which the plurality of nanoparticles exhibit plasmonic activity than in an other wavelength band that does not overlap the at least one wavelength band in which the plurality of nanoparticles exhibit plasmonic activity.

8. An electro-optical device according to claim 7, wherein the wavelength band corresponds to one of red or green light and the other wavelength band corresponds to blue light.

9. An electro-optical device according to claim 1, wherein the plurality of nanoparticles are arrayed on the substrate with random separations.

10. An electro-optical device according to claim 9, wherein:
the average separation between adjacent nanoparticles is a distance d;
the wavelength band in which plasmonic activity is exhibited by the arrayed nanoparticles is related to the distance d; and
the photo-activity exhibited by the linking molecules is in a wavelength band substantially co-extensive with the wavelength band in which the plasmonic activity is exhibited by the arrayed nanoparticles.

11. An electro-optical device according to claim 9, wherein the arrayed nanoparticles are separated by different distances such that the arrayed nanoparticles exhibit plasmonic activity in at least two wavelength bands.

12. An electro-optical device according to claim 11, wherein the plurality of nanoparticles include nanoparticles of different sizes.

13. An electro-optical device according to claim 12, wherein the plurality of nanoparticles include nanoparticles of different shapes.

14. An electro-optical device according to claim 1, wherein the plurality of nanoparticles include nanoparticles of different sizes.

15. An electro-optical device according to claim 1, wherein the linking molecules include multiple different linking molecules which exhibit photo -activity in multiple wavelength bands.

16. An electro-optical device according to claim 1, wherein at least a portion of the linking molecules are conjugated molecules comprised of at least one conjugated macrocycle.

17. An electro-optical device according to claim 1, wherein at least a portion of the linking molecules have a structure EG1-Cn1-[-MC-Cn2-]ₙ-EG2 wherein EG1 and EG2 are the same or different and are functional groups capable of bonding to a metal, Cn1 and Cn2 are the same or different and are conjugated connecting groups, MC is a chromophore selected from the group consisting of conjugated macrocycles, and n is an integer of at least 1, wherein if n is greater than 1 different chromophores may be present within the structure.
